(19) United States
(12) Patent Application Publication
(10) Pub. No.: US 2008/0113463 A1
(43) Pub. Date: May 15, 2008

(54) Method of fabricating GaN device with laser

(75) Inventors: Cheng-yi Liu, Jungli City (TW); Ching-Liang Lin, Taoyuan City (TW); Po-Han Chan, Chihshang Township (TW)

Correspondence Address: TROXELL LAW OFFICE PLLC, 5205 LEESBURG PIKE, SUITE 1404, FALLS CHURCH, VA, 22041, US

(73) Assignee: National Central University, Taoyuan County (TW)

(21) Appl. No.: 11/645,165

(22) Filed: Dec. 26, 2006

(30) Foreign Application Priority Data
Nov. 9, 2006 (TW) 095141521

(51) Int. Cl. H01L 33/00

(52) U.S. Cl. 438/46; 257/E33.025

(57) ABSTRACT

A laser is used in fabricating a thin film gallium nitride (GaN) light emitting diode (LED). The laser has a wave length to be absorbed by GaN. The laser is used to define a GaN grain. And the laser is used to lift off a substrate after obtaining a bonding layer of GaN. Fabrication procedure is thus simplified.

### FIELD OF THE INVENTION

The present invention relates to fabricating a gallium nitride (GaN) device; more particularly, relates to using a laser to define a light emitting diode (LED) grain and lift off a substrate for obtaining a grain of thin film GaN LED structure.

### DESCRIPTION OF THE RELATED ARTS

Substrates used in growing GaN epitaxy, like sapphire substrate or other lattice-matched substrate, do not have good heat conductivity and electricity conductivity in general. And they are hard to be cut. Hence, to smoothly remove substrate for epitaxy some technology, like wafer bonding and laser lifting-off, are developed and applied to transfer GaN epitaxy to another substrate with better electrical and thermal conductivities.

There are two methods for fabricating thin film GaN LED grain now. One is to define a specific size of GaN first on an epitaxy substrate by a dry etching. After defining the size of the grain, the wafer is processed using a bonding material to bond the specific size of GaN to a substrate with good thermal conductivity and electricity conductivity. By using this method, a good yield and a good grain characteristics can be obtained. Yet, the whole process is complex and the cost is high. The other method is to bond GaN on an epitaxy substrate with a substrate with good heat conductivity and electricity conductivity first. Then grains of specific size of GaN are defined by a dry etching. Yet, when applying this method on fabricating p-side down thin-GaN LEDs, bad photoelectrical characteristics may be obtained. It is because the light emitting layer may be too close to the bonding layer on etching the grains, since the thickness of p-GaN is about tens of nanometers.

Both of these two methods require lithography and dry etching; and both are of high cost. Hence, the prior arts do not fulfill users' requests on actual use.

### SUMMARY OF THE INVENTION

The main purpose of the present invention is to provide a way to define a thin film LED grain in a simple way with low cost.

To achieve the above purpose, the present invention is a method of fabricating a GaN device with laser, where a sapphire substrate is grown with an epitaxy of a p-side up GaN; then a bonding layer is uesd by bonding GaN with another substrate; then a laser is used to cut the substrate and GaN for defining a grain then the sapphire substrate is lifted off with the laser; then a buffer layer is etched to roughen a surface; and then, after being covered with a dielectric layer and etched out to deposit an n-type electrode, a thin film LED is obtained. Accordingly, a novel method of fabricating a GaN device with laser is obtained.

### BRIEF DESCRIPTIONS OF THE DRAWINGS

The present invention will be better understood from the following detailed descriptions of the preferred embodiments according to the present invention, taken in con junction with the accompanying drawings, in which

FIG. 1 is the flow view showing the first preferred embodiment according to the present invention;

FIG. 2 is the view showing the epitaxy structure;

FIG. 3 is the view showing another substrate bonded and the grain defined with laser;

FIG. 4 is the view showing the surface roughened after lifting off the substrate;

FIG. 5 is the view showing the structure of the thin film GaN LED;

FIG. 6 is the flow view showing the second preferred embodiment;

FIG. 7 is the view showing the epitaxy structure with the grain defined with laser;

FIG. 8 is the view showing bonding a substrate;

FIG. 9 is the view showing lifting off the substrate and roughening the surface; and

FIG. 10 is the view showing the structure of the thin film GaN LED.

### DESCRIPTIONS OF THE PREFERRED EMBODIMENTS

The following descriptions of the preferred embodiments are provided to understand the features and the structures of the present invention.

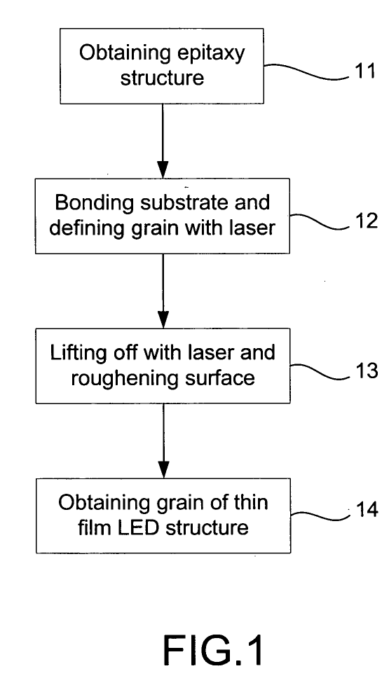

Please refer to FIG. 1, which is a flow view showing a first preferred embodiment according to the present invention. As shown in the figure, the present invention is a method of fabricating a gallium nitride (GaN) device with laser, comprising the following steps:

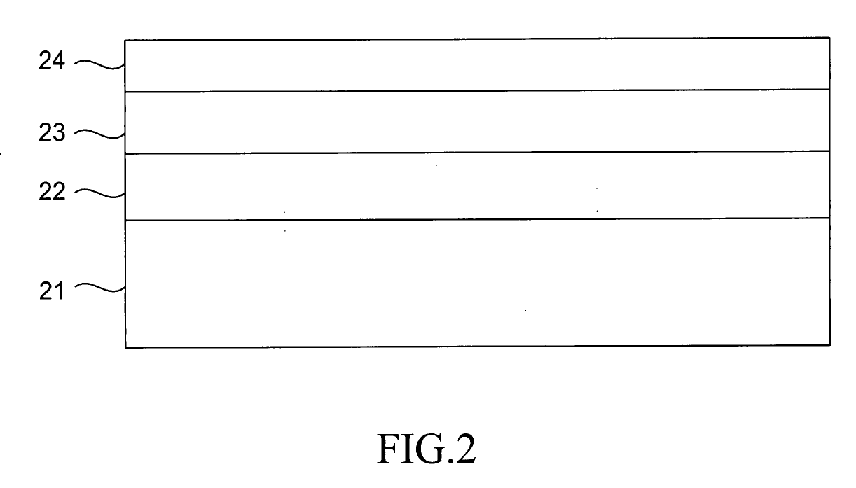

(a) Obtaining epitaxy structure 11: Please further refer to FIG. 2, which is a view showing an epitaxy structure. As shown in the figure, a substrate 21 is obtained first and is grown with a buffer layer 22, an n-type GaN 23 and a p-side up GaN 24 to obtain a wafer having an epitaxy structure 2, where the substrate 21 is made of sapphire, silicon carbide (SiC), gallium arsenide (GaAs), lithium dioxogallate (LiGaO₂) or aluminum nitride (AlN); the epitaxy structure 2 is an epitaxy layer of III-V group element, like GaAs, indium phosphide (InP), GaN, gallium indium nitride (GaInN),aluminum gallium indium nitride (AlGaInN), indium nitride (InN), gallium indium arsenic nitride (GaInAsN) or gallium indium phosphorous nitride (GaInPN); the epitaxy structure 2 is obtained through metal organic chemical vapor deposition (MOCVD), molecular beam epitaxy (MBE) or hydride vapor phase epitaxy (HVPE); and the epitaxy structure on the substrate 21 can be an n-side up GaN structure.

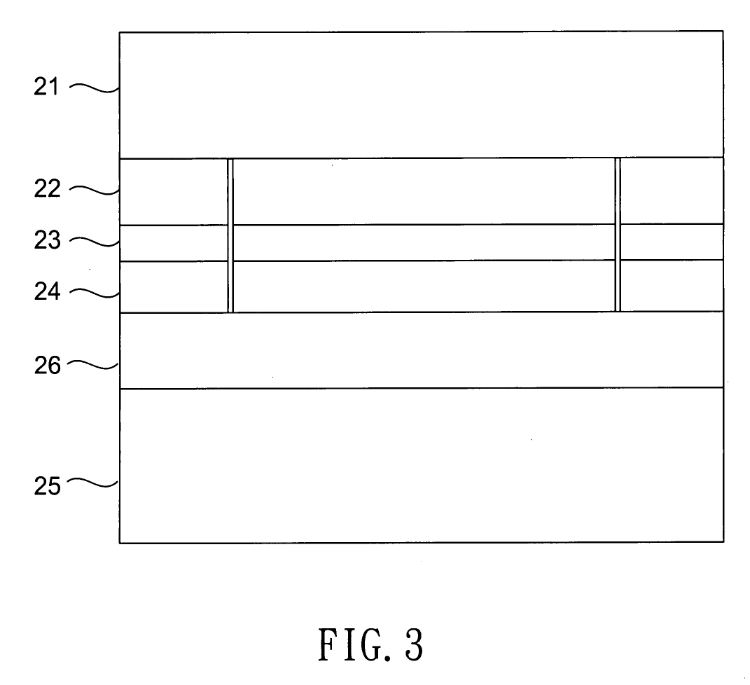

(b) Bonding substrate and defining grain with laser 12: Please further refer to FIG. 3, which is a view showing another substrate bonded and a grain defined with laser. As shown in the figure, the epitaxy structure 2 is bonded with another substrate 25 by using a bonding layer 26, and a surface of the substrate 21 is cut with laser to obtain a grain, where the another substrate 25 is bonded through a metal bonding, an organic polymer adhesion or an electroplating, such as Au-Au metal bonding, silver epoxy adhesion, conductive polymer adhesion or copper substrate electroplating; the another substrate 25 is made of copper (Cu), nickel (Ni), silicon (Si), aluminum nitride (AlN) or beryllium oxide (BeO); and the bonding layer 26 is made of an ohmic contact metal, a reflective metal or an under-bump metallization layer with bonding capacity.

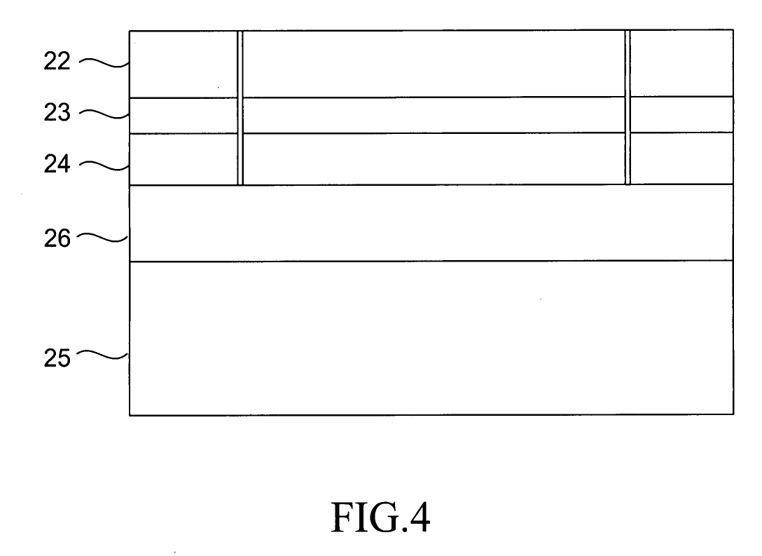

(c) Lifting off with laser and roughening surface 13: Please refer to FIG. 4, which is a view showing a surface roughened after lifting off the substrate. As shown in the figure, the substrate 21 is lifted off with laser and the buffer layer 22 is etched to roughen a surface, where the laser used in lifting off the substrate 21 is a solid state laser or an excimer laser, like Nd:YAG laser or KrF excimer laser; the etching on the buffer layer 22 is a physical etching or a chemical etching, like inductively coupled plasma (ICP) dry etching or photoelectrochemical wet-etching; and the laser used in lifting off the substrate 21 has a wavelength to be absorbed by the epitaxy structure 2.

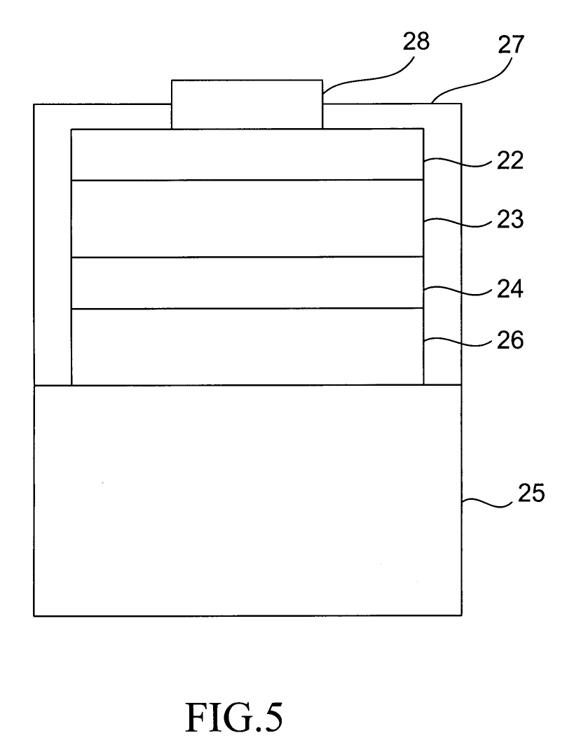

(d) Obtaining grain of thin film LED structure 14: Please further refer to FIG. 5, which is a view showing a structure of a thin film GaN light emitting diode (LED). As shown in the figure, at last, a dielectric layer 27 is covered on the grain and the buffer layer 22 and an n-type electrode 28 is etched out on the dielectric layer 27. Hence, a grain of thin film LED structure is obtained, where the dielectric layer 27 is a protecting layer for the grain and light extraction efficiency is enhenced by the dielectric layer 27.

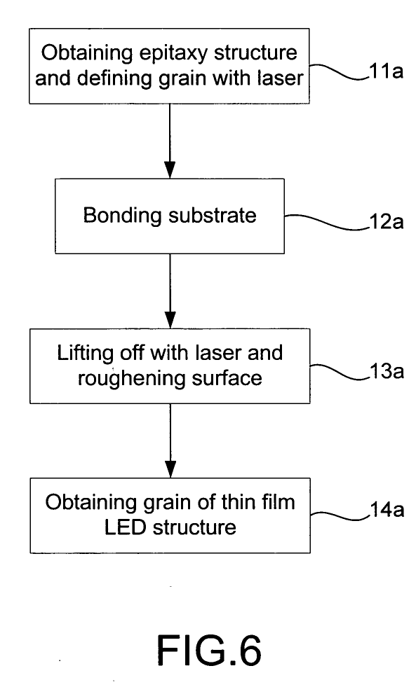

Please refer to FIG. 6, which is a flow view showing a second preferred embodiment according to the present invention. As shown in the figure, the present invention is a method of fabricating a GaN device with laser, comprising the following steps:

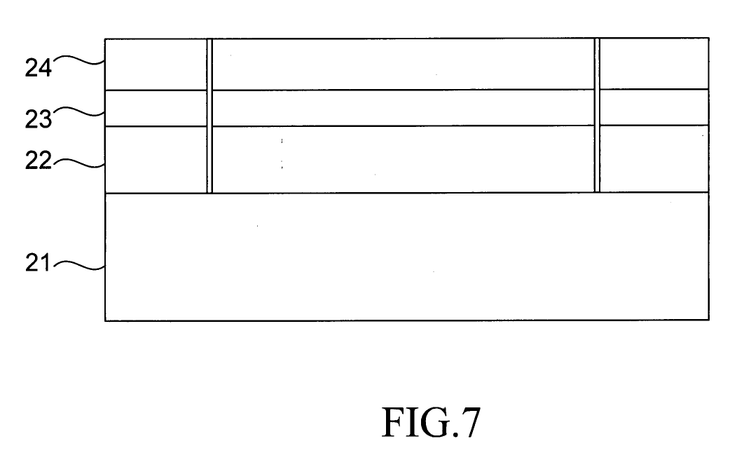

(a) Obtaining epitaxy structure and cutting with laser 11a: Please further refer to FIG. 7, which is a view showing an epitaxy structure with a grain defined with laser. As shown in the figure, a substrate 21 is obtained first and is grown with a buffer layer 22, an n-type GaN 23 and a p-side up GaN 24 to obtain a wafer having an epitaxy structure 2; and a surface of the substrate 21 is cut with a laser to obtain a grain, where the substrate 21 is made of sapphire, SiC, GaAs, LiGaO₂ or AlN; the epitaxy structure 2 is an epitaxy layer of III-V group element, like GaAs, InP, GaN, GaInN, AlGaInN, InN, GaInAsN or GaInPN; the epitaxy structure 2 is obtained through MOCVD, MBE or HVPE; and the epitaxy structure on the substrate 21 can be an n-side up GaN structure.

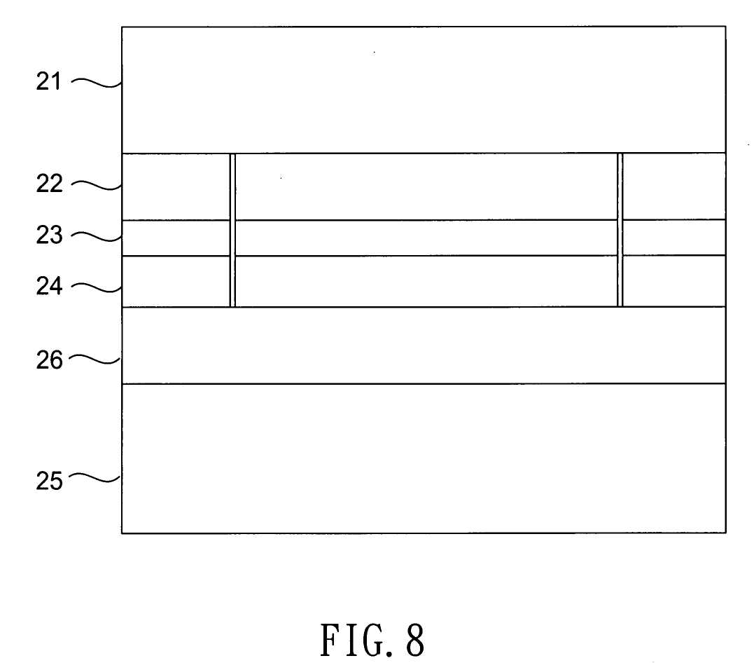

(b) Bonding substrate 12a: Please further refer to FIG. 8, which is a view showing another substrate bonded. As shown in the figure, the epitaxy structure 2 is bonded with another substrate 25 by using a bonding layer 26, where the another substrate 25 is bonded through a metal bonding, an organic polymer adhesion or an electroplating, such as Au-Au metal bonding, silver epoxy adhesion, conductive polymer adhesion or copper substrate electroplating; the another substrate 25 is made of Cu, Ni, Si, AlN and BeO; and the bonding layer 26 is made of an ohmic contact metal, a reflective metal or an under-bump metallization layer with bonding capacity.

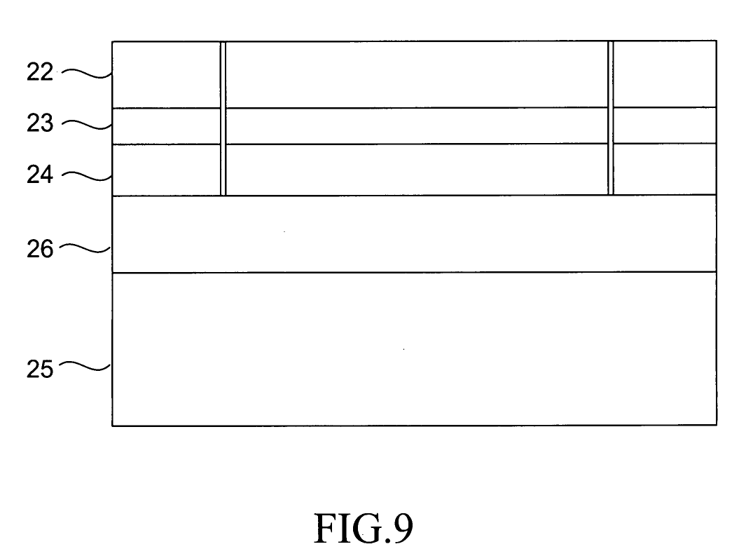

(c) Lifting off with laser and roughening surface 13a: Please refer to FIG. 9, which is a view showing a surface roughened after lifting off the substrate. As shown in the figure, the substrate 21 is lifted off with laser and the buffer layer 22 is etched to roughen a surface, where the laser used in lifting off the substrate 21 is a solid state laser or a excimer laser, like Nd:YAG laser or KrF excimer laser; the etching on the buffer layer 22 is a physical etching or a chemical etching like inductively coupled plasma (ICP) dry etching or photoelectrochemical wet-etching; and the laser used in lifting off the substrate 21 has a wavelength to be absorbed by the epitaxy structure 2.

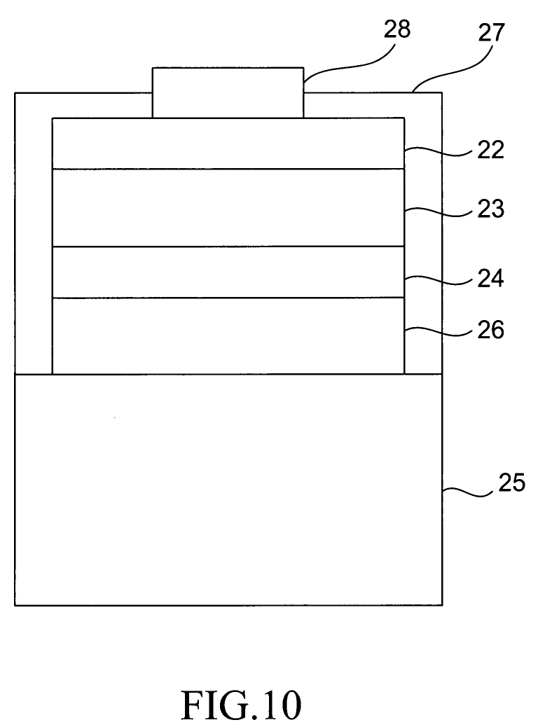

(d) Obtaining grain of thin film LED structure 14a: Please further refer to FIG. 10, which is a view showing a structure of a thin film GaN LED. As shown in the figure, at last, an dielectric layer 27 is covered on the grain and the buffer layer 22 and an n-type electrode 28 is etched out on the dielectric layer 27. Hence, a grain of thin film LED structure is obtained, where the dielectric layer 27 is a protecting layer for the grain and light extraction efficiency is enhenced by the dielectric layer 27.

To sum up, the present invention is a method of fabricating a GaN device with laser, where laser is used to define a grain and to lift off a substrate; and the laser, no matter a solid state laser or a gas state laser, has a wavelength to be absorbed by GaN.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of fabricating a gallium nitride (GaN) device with laser, comprising steps of:
(a) obtaining a substrate and growing a buffer layer, an n-type GaN and a p-side up GaN to obtain an epitaxy structure;
(b) bonding said epitaxy structure to bond with another substrate by using a bonding layer and defining a grain with laser;
(c) lifting off said substrate stripped out by laser illumination and etching said buffer layer to roughen a surface of said buffer layer; and
(d) deposing a dielectric layer on said grains and said buffer layer and etching out an n-type electrode to obtain a grain of thin film light emitting diode (LED) structure.

2. The method according to claim 1,
wherein said substrate is made of a material selected from a group consisting of sapphire, silicon carbide (SiC), gallium arsenide (GaAs), lithium dioxogallate (LiGaO₂) and aluminum nitride (AlN).

3. The method according to claim 1,
wherein said epitaxy structure is an epitaxy layer of III-V group elements; and
wherein said epitaxy structure is made of a material selected from a group consisting of GaAs, indium phosphide (InP), GaN, gallium indium nitride (GaInN), aluminum gallium indium nitride (AlGaInN), indium nitride (InN), gallium indium arsenic nitride (GaInAsN) and gallium indium phosphorous nitride (GaInPN).

4. The method according to claim 1,
wherein said epitaxy structure is obtained through a method selected from a group consisting of metal organic chemical vapor deposition (MOCVD), molecular beam epitaxy (MBE) and hydride vapor phase epitaxy (HVPE).

5. The method according to claim 1,
wherein said bonding with said another substrate is selected from a group consisting of a metal bonding, an organic polymer adhesion and an electroplating.

6. The method according to claim 5,
wherein said bonding is selected from a group consisting of Au (gold)-Au metal bonding, silver epoxy adhesion, conductive polymer adhesion and electroplating.

7. The method according to claim 1,
wherein said another substrate is made of a material selected from a group consisting of copper (Cu), nickel (Ni), silicon (Si), aluminum nitride (AlN) and beryllium oxide (BeO).

8. The method according to claim 1,
wherein said bonding layer is made of a material selected from a group consisting of an ohmic contact metal, a reflective metal and an under-bump metallization layer with bonding capacity; and
wherein said bonding layer is electrically connected with GaN.

9. The method according to claim 8,
wherein said bonding layer is a bonding selected from a group consisting of Au-Si, Au-Ge(germanium), Au-Sn(tin), Pd-In (indium) and Pb-Sn

10. The method according to claim 1,
wherein said laser used in lifting off said substrate is selected from a group consisting of a solid state laser and an excimer laser.

11. The method according to claim 10,
wherein said laser used in lifting off said substrate is selected from a group consisting of Nd:YAG laser and KrF excimer laser.

12. The method according to claim 1,
wherein said etching on said buffer layer is selected from a group consisting of a physical etching and a chemical etching.

13. The method according to claim 12,
wherein said etching on said buffer layer is selected from a group consisting of inductively coupled plasma (ICP) dry etching and photoelectrochemical wet-etching.

14. The method according to claim 1,
wherein said dielectric layer is a protecting layer to said grain and is coordinated in light extraction.

15. A method of fabricating a GaN device with laser, comprising steps of:
(a) obtaining a substrate and growing a buffer layer, an n-type GaN and a p-side up gallium nitride (GaN) to obtain an epitaxy structure and defining a grain with laser;
(b) bonding said epitaxy structure to bond with another substrate by using a bonding layer;
(c) lifting off said substrate striiped out by stripped out by laser illumination and etching said buffer layer to roughen a surface of said buffer layer; and
(d) deposing a dielectric layer on said grains and said buffer layer and etching out a n n-type electrode to obtain a grain of thin film LED structure.
